(19) United States
(12) Patent Application Publication
(10) Pub. No.: US 2016/0365459 A1
(43) Pub. Date: Dec. 15, 2016

(54) THIN FILM TRANSISTOR, MANUFACTURING METHOD OF THE SAME, AND DISPLAY DEVICE WITH THE THIN FILM TRANSISTOR

(71) Applicant: Samsung Display Co., Ltd., Yongin-si (KR)

(72) Inventors: Sung Jin HONG, Yongin-si (KR); Jae Woong KANG, Yongin-si (KR); Jong Hyuk KANG, Yongin-si (KR); Dae Hyun KIM, Yongin-si (KR); Jae Byung PARK, Yongin-si (KR); Joo Yeol LEE, Yongin-si (KR); Hyun Deok IM, Yongin-si (KR); Hyun Min CHO, Yongin-si (KR); Nam Seok ROH, Yongin-si (KR)

(21) Appl. No.: 15/010,169

(22) Filed: Jan. 29, 2016

(30) Foreign Application Priority Data
Jun. 9, 2015 (KR) 1020150081200

(51) Int. Cl. H01L 29/786; H01L 27/12; G02F 1/1333; H01L 29/423; G02F 1/1368; H01L 29/66; H01L 27/32

(52) U.S. Cl. CPC H01L 29/78669; H01L 29/78603; H01L 29/66765; H01L 27/1222; H01L 27/1262; H01L 27/3248; H01L 27/322; H01L 29/42384; G02F 1/1368; G02F 1/133345; H01L 2227/323

(57) ABSTRACT

A thin film transistor includes an insulating pattern disposed on a substrate, a gate electrode disposed on the insulating pattern, a gate insulating layer disposed on the gate electrode, a semiconductor layer disposed on the gate insulating layer, and a source electrode and a drain electrode, the source electrode and the drain electrode being disposed on the semiconductor layer and distanced apart from each other. The gate electrode surrounds an upper surface and a side surface of the insulating pattern and overlaps a first portion of a substrate surface.

### CROSS-REFERENCE TO RELATED APPLICATION

This application claims priority from and the benefit of Korean Patent Application No. 10-2015-0081200, filed on Jun. 9, 2015, which is hereby incorporated by reference for all purposes as if fully set forth herein.

### BACKGROUND

Field

Exemplary embodiments relate to a thin film transistor. More particularly, exemplary embodiments relate to a method of manufacturing the same and a display device including the thin film transistor.

Discussion of the Background

A thin film transistor may be used as a switching device in a display device such as a liquid crystal display and an organic light emitting diode display. The thin film transistor may include a gate electrode connected to a gate line transmitting scan signals, a source electrode connected to a data line transmitting data signals to be applied to pixel electrode, a drain electrode facing the source electrode and a semiconductor layer electrically connected to the source electrode and the drain electrode.

Mobility and leakage current of the thin film transistor may be greatly affected by material and state of a channel layer, which is a path through which a carrier moves.

The thin film transistor applied in current display devices has a channel layer that largely consists of an amorphous silicon layer. Amorphous silicon thin film transistors can be formed uniformly on a large substrate with lost cost. However, amorphous silicon thin film transistors have a low mobility of electric charge.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a thin film transistor with fast driving speed and an improved opening ratio. Exemplary embodiments also provide a method for manufacturing the thin film transistor with fast driving speed and an improved opening ratio and a display device including the thin film transistor with fast driving speed and an improved opening ratio.

Additional aspects will be set forth in the detailed description which follows, and, in part, will be apparent from the disclosure, or may be learned by practice of the inventive concept.

An exemplary embodiment discloses a thin film transistor that includes an insulating pattern disposed on a substrate, a gate electrode disposed on the insulating pattern, a gate insulating layer disposed on the gate electrode, a semiconductor layer disposed on the gate insulating layer, and a source electrode and a drain electrode, the source electrode and the drain electrode being disposed on the semiconductor layer and distanced apart from each other. The gate electrode surrounds an upper surface and a side surface of the insulating pattern and overlaps a portion of a substrate surface.

An exemplary embodiment discloses a method of manufacturing a thin film transistor including forming an insulating pattern on a substrate, forming a gate electrode on the insulating pattern, forming a gate insulating layer on the gate electrode, forming a semiconductor layer on the gate insulting layer, and forming a source electrode and a drain electrode on the semiconductor layer, the source electrode and the drain electrode being distanced apart from each other on the semiconductor layer. The gate electrode surrounds an upper surface and a side surface of the insulating pattern and overlaps a first portion of a substrate surface.

An exemplary embodiment discloses a display device including a display element and a thin film transistor configured to provide a driving signal to the display element. The thin film transistor includes an insulating pattern disposed on a substrate, a gate electrode disposed on the insulating pattern, a gate insulating layer disposed on the gate electrode, a semiconductor layer disposed on the gate insulating layer, and a source electrode and a drain electrode disposed on the semiconductor layer, the source electrode and the drain electrode being disposed to be distanced apart from each other. The gate electrode surrounds an upper surface and a side surface of the insulating pattern and overlaps a portion of a substrate surface.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a cross-sectional view of a thin film transistor according to an exemplary embodiment.

FIGS. 2A, 2B, 2C, 2D, 2E, 2F, 2G, 2H, 2I, 2J, 2K, 2L, 2M, and 2N are cross-sectional views of a method for manufacturing a thin film transistor according to an exemplary embodiment.

FIG. 3 is a cross-sectional view of a thin film transistor according to an exemplary embodiment.

FIG. 4 is a cross-sectional view of a thin film transistor according to an exemplary embodiment.

FIG. 5 is a circuit diagram illustrating a liquid crystal display among various display devices with a thin film transistor according to an exemplary embodiment.

FIG. 6A is a plan view of a liquid crystal display according to an exemplary embodiment.

FIG. 6B is a cross-sectional view of a liquid crystal display taken along section line I-I′ of FIG. 6A.

FIGS. 7A, 8A, 9A, and 10A are plan views of a method for manufacturing a liquid crystal display in accordance with an embodiment.

FIGS. 7B, 8B, 9B, and 10B illustrate cross-sectional views taken along sectional lines I-I′ of FIGS. 7A, 8A, 9A and 10A.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms “first,” “second,” etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

In an exemplary embodiment, a thin film transistor is a bottom gate thin film transistor with a gate electrode formed on a lower portion of a channel layer.

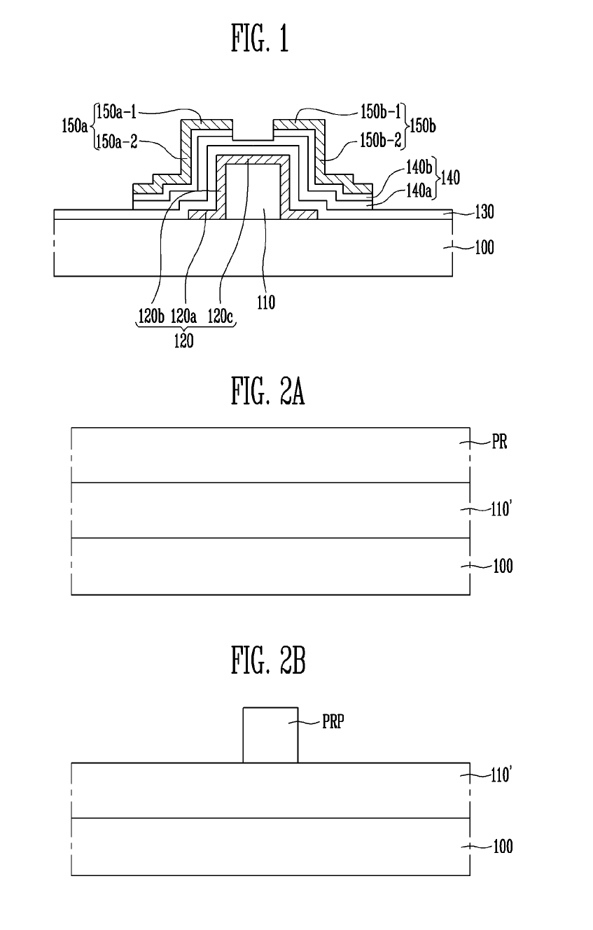

FIG. 1 is a cross-sectional view of a thin film transistor according to an exemplary embodiment.

Referring to FIG. 1, the thin film transistor may include an insulating pattern 110 formed on a substrate 100, a gate electrode 120 formed on the insulating pattern 110, a semiconductor layer 140 formed on the gate electrode 120, a source electrode 150a and a drain electrode 150b formed on the semiconductor layer 140.

The substrate 100 may be a transparent substrate and include a transparent material such as glass, quartz, ceramic, and/or plastic. The substrate may be a silicon substrate. The substrate 100 may also be flexible substrate (e.g., may include plastic).

The insulating pattern 110 may be provided on a surface of the substrate 100. The insulating pattern 110 may include a material with a high penetration ratio (e.g., at least one of silicon nitride (SiN_{X}), carbon-injected silicon oxide (SiOC), and an organic polymer).

The gate electrode 120 may be formed of a conductive material (e.g., a metal). The gate electrode 120 may be formed of a single metal or multiple metals. For example, the gate electrode may be formed of an alloy of two or more types of metal. In addition, the gate electrode 120 may be formed of a single layer or multiple layers.

The gate electrode 120 may include a first portion 120a overlapping a portion of the surface of the substrate 100 along an edge of the insulating pattern 110, a second portion 120b contacting a side surface of the insulating pattern 110 and extending from the first portion 120a to a third portion 120c of the gate electrode 120. The third portion 120c of the gate electrode may contact an upper surface of the insulating pattern 110 and extend from the second portion 120b to another part of the second portion 120b.

Since the second portion 120b of the gate electrode 120 may surround the side surface of the insulating pattern 110 and extend vertically from the first portion 120a to the third portion 120c, a width of a line (i.e., a data line DL, a gate line GL, and/or a storage line STL) may be substantively reduced. A gate insulating layer 130 may be disposed on the gate electrode 120.

The gate insulating layer 130 may be formed on the substrate 100 in accordance with a shape of the gate electrode 120. The gate insulating layer 130 may include an organic insulating material and/or an inorganic insulating material (e.g., silicon oxide or silicon nitride).

The semiconductor layer 140 may include an active layer 140a and an ohmic contact layer 140b. The active layer 140a may be formed on the gate insulating layer 130. The active layer 140a may not include any injected impurities. The ohmic contact layer 140b may be disposed on the active layer 140a. Impurities may be injected into the ohmic contact layer 140b. The impurities may vary depending on the type of the thin film transistor. The active layer 140a and the ohmic contact layer 140b may be formed on the gate insulating layer 130 in accordance with the shape of the gate electrode 120.

In the semiconductor layer 140, an area between the source electrode 150a and the drain electrode 150b may be a channel portion.

The source electrode 150a may be directly disposed on the semiconductor layer 140 to cover a portion of the surface of the semiconductor layer 140. The source electrode 150a may include a first portion 150a-1 substantially parallel to an upper surface of the semiconductor layer 140 and a second portion 150a-2 substantially parallel to a side surface of the semiconductor layer 140.

The drain electrode 150b may be disposed on the semiconductor layer 140 to be distanced apart from the source electrode 150a. The drain electrode 150b may include a first portion 150b-1 substantially parallel to the upper surface of the semiconductor layer 140 and a second portion 150b-2 substantially parallel to the side surface of the semiconductor layer 140.

The source electrode 150a may include a conductive material (e.g., a metal). Similarly, the drain electrode 150b may include a conductive material (e.g., a metal). Each of the source electrode 150a and the drain electrode 150b may be formed of a single metal or multiple metals. For example, the gate electrode may be formed of an alloy of two or more types of metal. In addition, each of the source electrode 150a and the drain electrode 150b may be formed of a single layer or multiple layers.

Each of the source electrode 150a and the drain electrode 150b may be formed on the upper surface and the side surface of the semiconductor layer 140. Accordingly, in the semiconductor layer 140, the channel portion may be formed both on the upper surface and the side surface of the semiconductor layer 140.

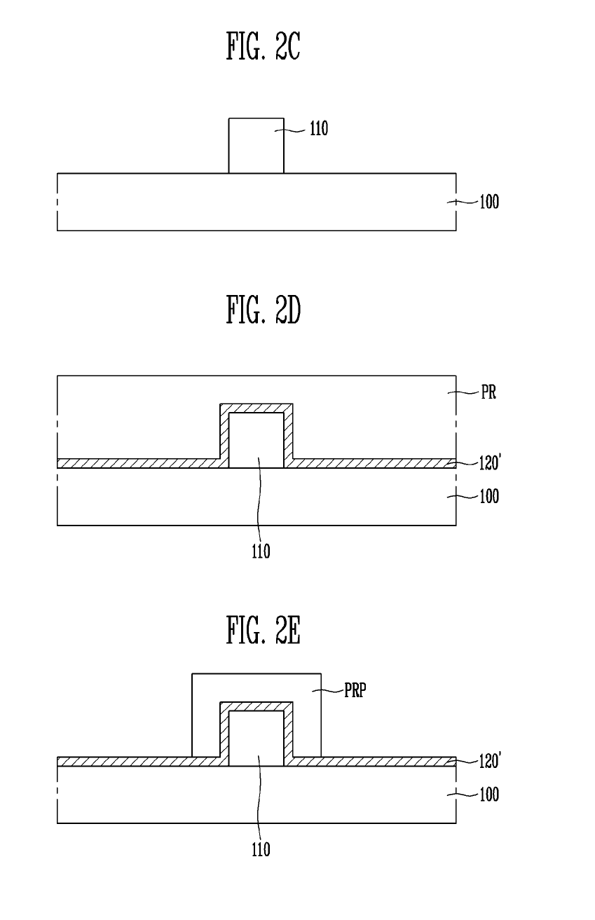

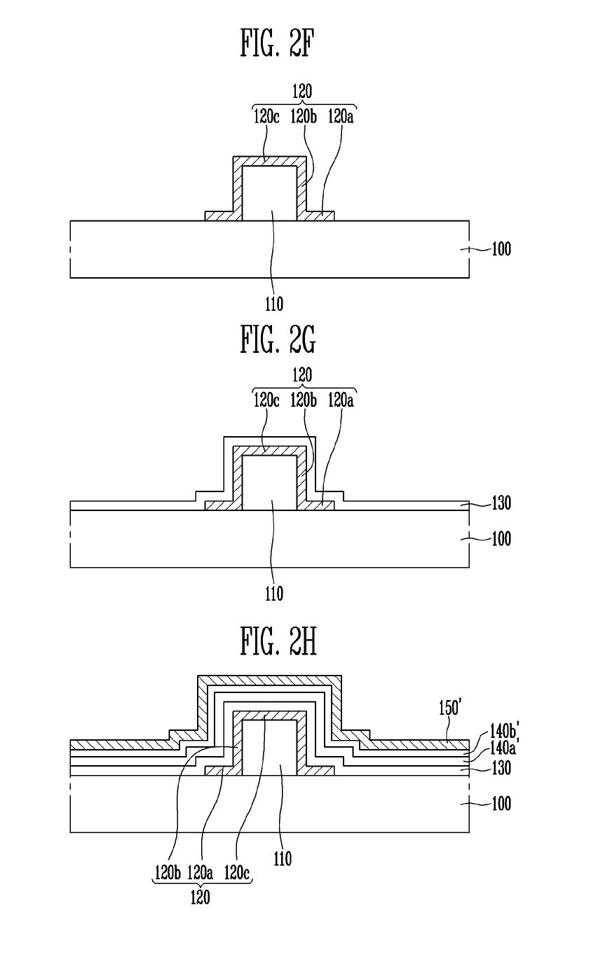

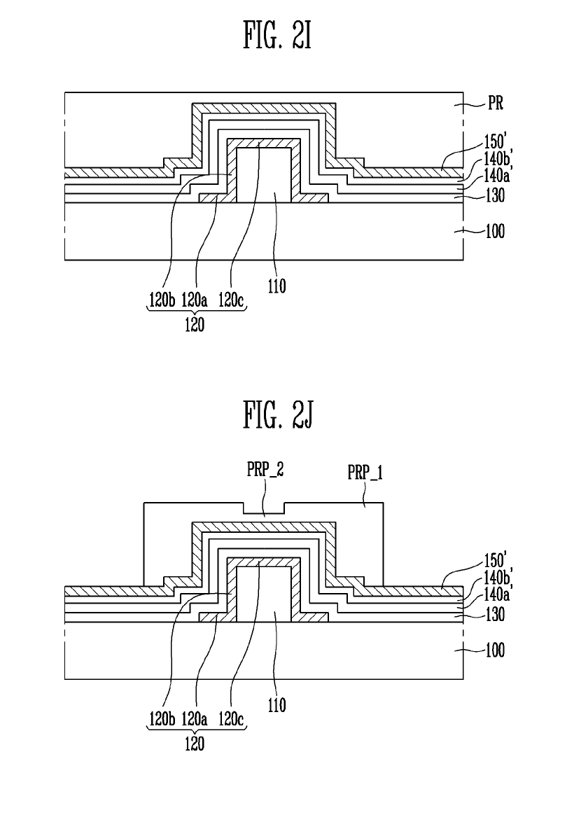

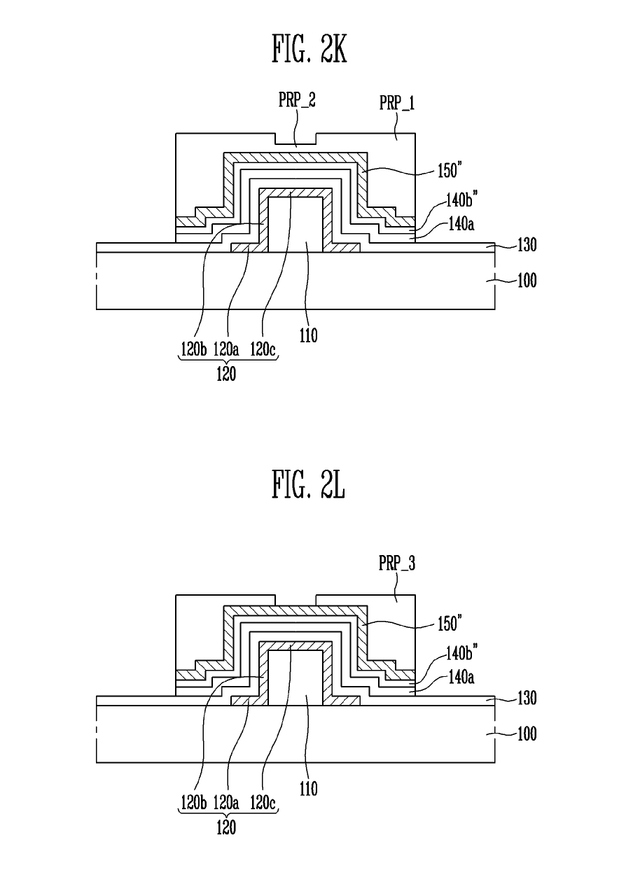

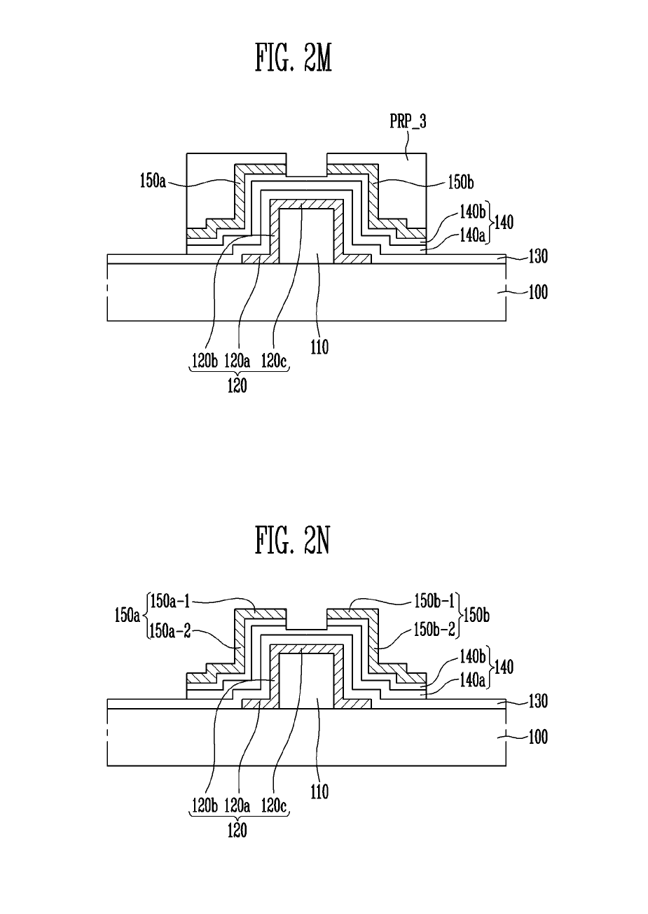

FIGS. 2A, 2B, 2C, 2D, 2E, 2F, 2G, 2H, 2I, 2J, 2K, 2L, 2M, and 2N are cross-sectional views of a method for manufacturing a thin film transistor according to an exemplary embodiment.

Referring to FIG. 2A, an insulating material layer 110′ may be formed on a substrate 100. The insulating material layer 110′ may be formed of a material having a high transmittivity (e.g., at least one of silicon nitride (SiN_{X}), carbon-injected silicon oxide (SiOC), and an organic polymer). A photoresist layer PR may be formed on the insulating material layer 110′.

Referring to FIG. 2B, a photoresist pattern PRP may be formed on the insulating material layer 110′ using photolithography. If the insulating material layer 110′ is etched with the photoresist pattern PRP as a mask, an insulating pattern 110 may be formed with the shape corresponding to the photoresist pattern PRP, as shown in FIG. 2C. The photoresist pattern PRP on the insulating pattern 110 may be removed after forming the insulating pattern 110.

Referring to FIG. 2D, a first conductive layer 120′ may be formed on the insulating pattern 110 and the substrate 100. The first conductive layer 120′ may include a single metal or multiple metals. The first conductive layer 120′ may include an alloy of a metal or multiple metals. The first conductive layer 120′ may include at least one of molybdenum (Mo), tungsten (W), aluminum neodymium (AlNd), titanium (Ti), aluminum (Al), and silver (Ag). The first conductive layer may include an alloy of at least one of molybdenum (Mo), tungsten (W), aluminum neodymium (AlNd), titanium (Ti), aluminum (Al), and silver (Ag). The first conductive layer 120′ may include a single layer. To reduce wire resistance the first conductive layer 120′ may include a low resistant material such as molybdenum (Mo), aluminum (Al), or silver (Ag). For example, the first conductive layer 120′ may include multiple layers of at least one of molybdenum (Mo), aluminum (Al), and silver (Ag).

A photoresist layer PR may be formed on the first conductive layer 120′.

Referring to FIG. 2E, photolithography may be use to form the photoresist pattern PRP on the first conductive layer 120′. If the first conductive layer 120′ is etched with the photoresist pattern PRP as a mask, a gate electrode 120 may be formed with the shape corresponding to the photoresist pattern PRP, as shown in FIG. 2F. The first conductive layer 120′ may be etching using an anisotropic etching method. The photoresist pattern PRP on the gate electrode 120 may be removed.

Here, the gate electrode 120 may include a first portion 120a contacting a portion of the surface of the substrate 100, a second portion 120b contacting a side surface of the insulating pattern 110 and extending from the first portion 120a to a third portion 120c. The third portion 120c of the gate electrode may contact an upper surface of the insulating pattern 110 and extend from the second portion 120b to another part of the second portion 120b.

Here, the second portion 120b of the gate electrode 120 may surround the side surface of the insulating pattern 110 and may extend vertically from the first portion 120a to the third portion 120c.

Referring to FIG. 2G, the gate insulating layer 130 may be formed on the gate electrode 120 and the substrate 100. The gate insulating layer 130 may include an organic insulating material and/or an inorganic insulating material. For example, the gate insulating layer 130 may include an inorganic insulating material such as silicon oxide or silicon nitride.

Referring to FIG. 2H, an amorphous silicon layer 140a′, an impure amorphous silicon layer 140b′, and a second conductive layer 150′ may be sequentially formed on the gate insulating layer 130. The second conductive layer 150′ may be formed of a single metal, two or more metals, or an alloy of metals. The second conductive layer 150′ may include at least one of molybdenum (Mo), tungsten (W), molybdenum tungsten (MoW), aluminum neodymium (AlNd), titanium (Ti), aluminum (Al), and silver (Ag). The second conductive layer 150′ may include an alloy of at least one of molybdenum (Mo), tungsten (W), molybdenum tungsten (MoW), aluminum neodymium (AlNd), titanium (Ti), aluminum (Al), and silver (Ag). The second conductive layer 150′ may be a single layer or multiple layers. As multiple layers, the second conductive layer 150′ may include a low resistant material to reduce wire resistance such as molybdenum (Mo), aluminum (Al), or silver (Ag).

Referring to FIG. 2I, a photoresist layer PR may be formed on the second conductive layer 150′.

Referring to FIG. 2J, the first photoresist pattern PRP_1 and the second photoresist pattern PRP_2 have different thickness. The first photoresist pattern PRP_1 and the second photoresist pattern PRP_2 may be formed on the second conductive layer 150′ using photolithography with a half-tone mask. The first photoresist pattern PRP_1 may correspond to an area a source electrode and a drain electrode to be formed, and the second photoresist pattern PRP_2 may correspond to an area between the source electrode and the drain electrode (i.e., a channel portion).

The second conductive layer 150′, the impure amorphous silicon layer 140b′ and the amorphous silicon layer 140a′ may be etched using the first photoresist pattern PRP_1 and the second photoresist pattern RPRP_2 as mask.

Referring to FIG. 2K, a second conductive pattern 150″, an impure amorphous silicon pattern 140b″, and an active layer 140a may be formed. Each of the second conductive pattern 150″, the impure amorphous silicon pattern 140b″, and the active layer 140a has a shape corresponding to the first photoresist pattern PRP_1 and the second photoresist pattern PRP_2.

Referring to FIG. 2L, by performing an ashing process using oxygen, plasma, and the like, the second photoresist pattern PRP_2 may be removed. A portion of the second conductive pattern 150″ may be exposed (i.e., not covered by the any layer or photoresist pattern such as the second photoresist pattern PRP_2) and a third photoresist pattern PRP_3 having a thickness less than the first photoresist pattern PRP_1 may be formed on the second conductive pattern 150″.

Referring to FIG. 2M, the second conductive pattern 150″ may be etched with the third photoresist pattern PRP_3 as mask. A source electrode 150a and a drain electrode 150b which are distanced apart from each other may be formed as a result of etching the second conductive pattern 150″. When the second conductive pattern 150″ is etched, the impure amorphous silicon pattern 140b″ that is exposed in the channel portion may be partially removed, and an ohmic contact layer 140b may be formed. The active layer 140a and the ohmic contact layer 140b may form a semiconductor layer 140.

The third photoresist pattern PRP_3 on the source electrode 150a and the drain electrode 150b may be removed as shown in FIG. 2N.

The source electrode 150a may include a first portion 150a-1 that is substantially parallel to an upper surface of the semiconductor layer 140 and a second portion 150a-2 having a vertical structure that is substantially parallel to a side surface of the semiconductor layer 140.

The drain electrode 150b may include a first portion 150b-1 that is substantially parallel to the upper surface of the semiconductor layer 140 and a second portion 150b-2 having a vertical structure that is substantially parallel to the side surface of the semiconductor layer 140.

As the second portion 150a-2 of the source electrode 150a and the second portion 150b-2 of the drain electrode 150b include a shape having a vertical structure which surrounds the side surface of the semiconductor layer 140, a width of a line (i.e., a data line DL, a gate line GL, and/or a storage line STL) may be substantively reduced.

As for a thin film transistor in accordance with a first embodiment, the semiconductor layer 140, the source electrode 150a, and the drain electrode 150b may be formed in accordance with the shape of the gate electrode 120, which contacts a side surface and an upper surface of the insulating pattern 110, thereby forming a channel portion. Therefore, as the channel portion extends to, not only the upper surface of the semiconductor layer 140, but also the side surface of the semiconductor layer 140, electrical characteristics may be enhanced, thereby implementing fast operating speed.

For the thin film transistor in accordance an exemplary embodiment, as a portion of the gate electrode 120, a portion of the source electrode 150a, and a portion of the drain electrode 150b are formed in a shape having a vertical structure, the width of the line (i.e., a data line DL, a gate line GL, and/or a storage line STL) may be substantively reduced.

The thin film transistor according to an exemplary embodiment may be applied in various display devices.

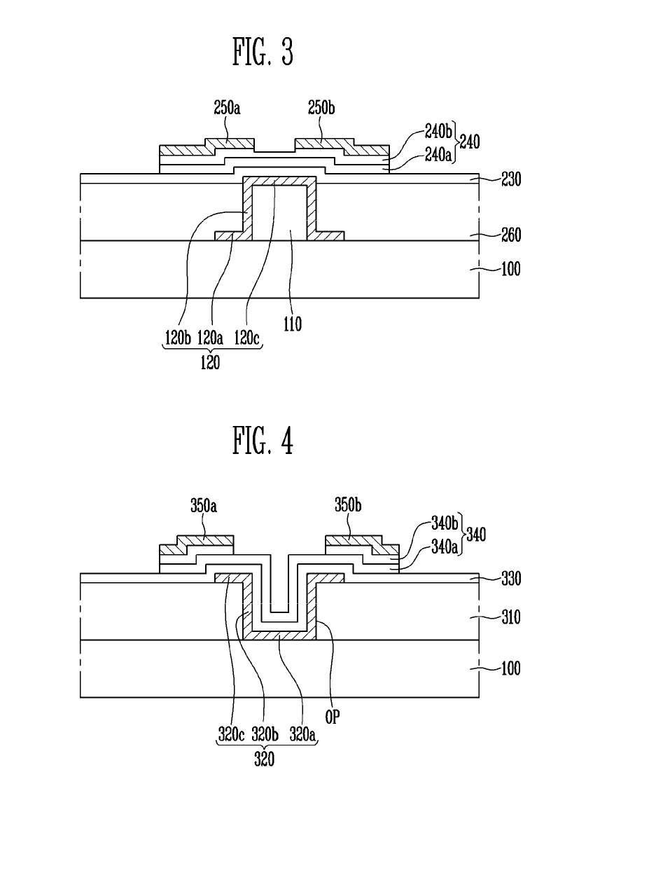

FIG. 3 is a cross-sectional view of a thin film transistor according to an exemplary embodiment. In order to avoid repetitive description, differences between the thin film transistors according to the exemplary embodiments illustrated in FIG. 1 and FIG. 3 will be mainly described. Any portion that is not described may be as described with reference to the thin film transistor described in reference to FIG. 1. Same reference numeral refers to same component, and similar numeral refers to similar component.

Referring to FIG. 3, a thin film transistor according to an exemplary embodiment includes an insulating pattern 110 formed on a substrate 100, a gate electrode 120 formed on the insulating pattern 110, a filling layer 260 surrounding a side surface of the gate electrode 120, a gate insulating layer 230 formed on upper surfaces of the filling layer 260 and the gate electrode 120, a semiconductor layer 240 formed on the gate insulating layer 230, and a source electrode 250a and a drain electrode 250b separated from each other on the semiconductor layer 240.

The gate electrode 120 may include a first portion 120a contacting a portion of a surface of the substrate 100, a second portion in contact with the side surface of the insulating pattern 110 and extending from the first portion 120a to a third portion 120c. The gate electrode 120 also includes a third portion 120c in contact with the upper surface of the insulating pattern 110 and extending from the second portion 120b to another part of the second portion 120b.

The filling layer 260 may be formed of any one selected from a transparent material layer or a color filter layer. The filling layer 260 may surround the first portion 120a and the second portion 120b of the gate electrode 120. Since the filling layer 260 surrounds the first and second portions 120a and 120b of the gate electrode 120, the third portion 120c of the gate electrode 120 may be exposed to outside the filling layer 260. Since the third portion 120c of the gate electrode 120 is exposed outside the filling layer 260, the area that the gate electrode 120 overlaps the source electrode 250a or the drain electrode 250b may be minimized.

Accordingly, a parasitic capacitance which may occur between the gate electrode 120 and the source electrode 250a or a parasitic capacitance which may occur between the gate electrode 120 and the drain electrode 250b may be very small. Therefore, reliable driving of the thin film transistor is possible.

In addition, since the filling layer 260 may surround both the first portion 120a of the gate electrode 120 and the second portion 120b of the gate electrode 120, the step height due to the shape of the gate electrode 120 may be reduced. The step height of the gate insulating layer 230 formed on the gate electrode 120 may be also reduced, and thus a defect occurring due to the step height of the gate insulating layer 230 may be minimized.

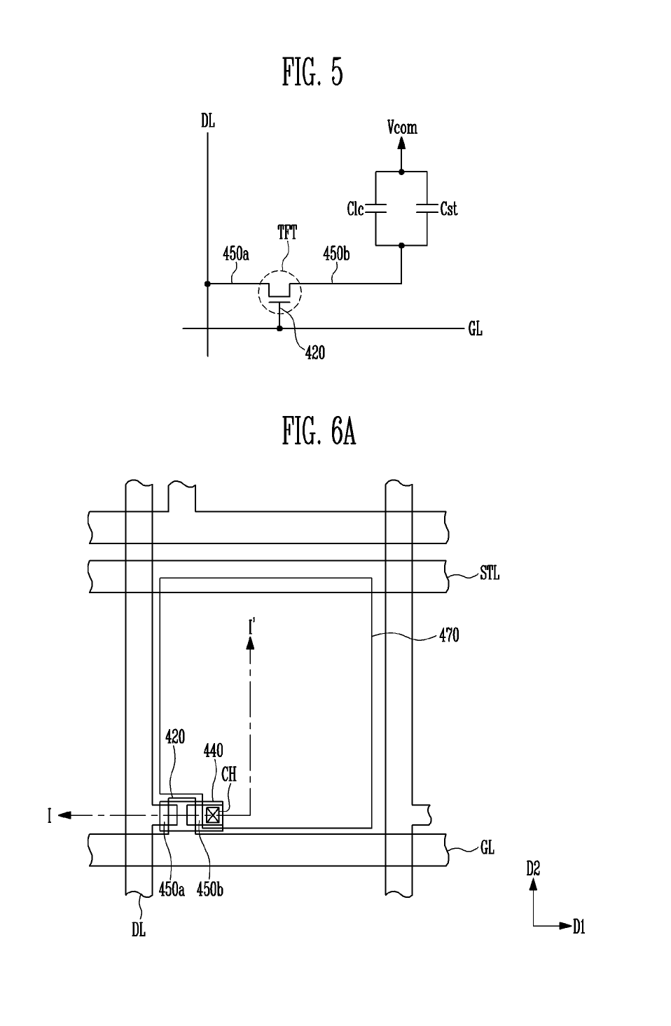

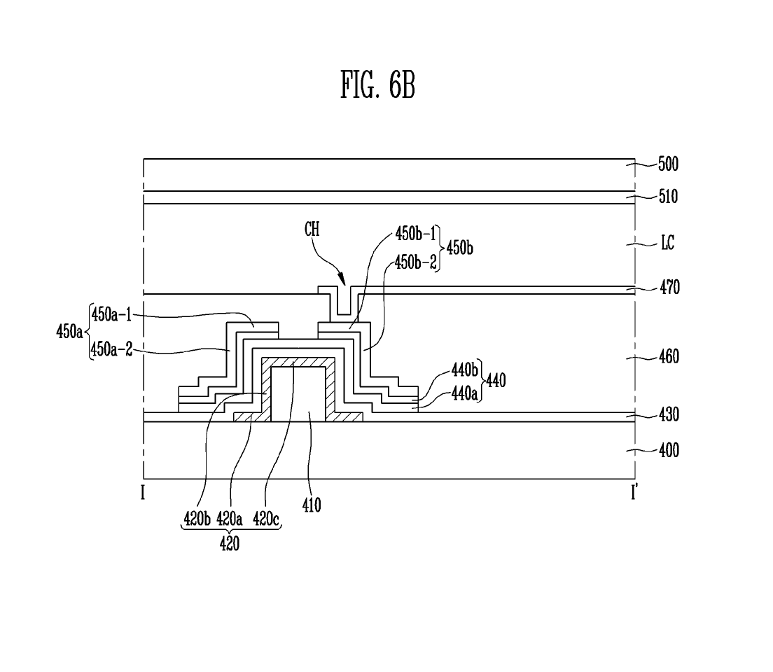

FIG. 4 is a cross-sectional view of a thin film transistor in accordance with a third embodiment. With respect to the thin film transistor according to the third embodiment, in order to avoid repetitive description, difference between the thin film transistor according to the third embodiment and the thin film transistor according to the first embodiment will be mainly described. Any portion that is not described in embodiment may be as described with reference to the thin film transistor in accordance with the first embodiment. Same reference numeral refers to same component, and similar numeral refers to similar component.

Referring to FIG. 4, a thin film transistor according to an exemplary embodiment includes an insulating pattern 310 formed on a substrate 100 and including an opening portion OP, a gate electrode 320 formed in the opening portion OP of the insulating pattern 310, a gate insulating layer 330 formed on the gate electrode 320 and the insulating pattern 310, a semiconductor layer 340 formed on the gate insulating layer 330, and a source electrode 350a and a drain electrode 350b separate from each other on the semiconductor layer 340.

The insulating pattern 310 may be provided on the substrate 100 and include a material with a high penetration ratio (e.g., at least one of silicon nitride (SiN_{X}), carbon-injected silicon oxide (SiOC), and an organic polymer). The insulating pattern 310 may be formed by patterning an insulating material layer formed on all surfaces of the substrate 100 with photolithography.

The insulating pattern 310 may include at least one opening portion OP, which exposes a portion of the surface of the substrate 100 (i.e., not covered by the insulating pattern). A shape of the opening portion OP may vary depending on an angle of inclination of a side surface of the insulating pattern 310. The opening portion OP may also be U- or V-shaped.

The gate electrode 320 may be formed of a conductive material (e.g., a metal). The gate electrode 320 may be formed of a single metal or two or more types of metal. The gate electrode 320 may be an alloy of two or more metals. In addition, the gate electrode 320 may be formed of a single layer or multiple layers.

The gate electrode 320 may include a first portion 320a contacting a portion of the surface of the substrate 100 in the opening portion OP, a second portion 320b contacting a side surface of the insulating pattern 310 and extending from the first portion 320a to a third portion 320c of the gate electrode. The third portion 320c may contacting an upper surface of the insulating pattern 310 and extend from the second portion 320b or another part of the second portion 320b.

Since the second portion 320b of the gate electrode 320 includes a vertical shape surrounding the side surface of the insulating pattern 310, a width of a line (i.e., a data line DL, a gate line GL, and/or a storage line STL) may be substantively reduced. A gate insulating layer 330 may be provided on the gate electrode 320.

The gate insulating layer 330 generally uses an inorganic insulating material. Since such gate insulating layer 330 is thin, it may be formed in accordance with a step height of the gate electrode 320.

The semiconductor layer 340 may include an active layer 340a and an ohmic contact layer 340b. The active layer 340a may be formed on the gate insulating layer 330, and no impurities may be injected into the active layer 340a. The ohmic contact layer 340b may be disposed on the active layer 340a, and impurities may be injected into the ohmic contact layer 340b. The active layer 340a may be formed on the gate insulating layer 330 in accordance with the shape of the gate electrode 320.

The active layer 340a may be formed on the gate insulating layer 330 and extend to an area corresponding to the source electrode 350a, an area corresponding to the drain electrode 350b, and an area overlapping the opening portion OP of the insulating pattern 310.

Since the active layer 340a extends to not only areas corresponding to the source electrode 350a and the drain electrode 350b, but also to the opening portion OP of the insulating pattern 310, a channel portion of the semiconductor layer 340 may extend as well.

Since the gate electrode 320 includes a vertical shape, a width of a line (i.e., a data line DL, a gate line GL, and/or a storage line STL) may be substantively reduced. As a result, the opening ratio of display device with the thin film transistor in accordance an exemplary embodiment may be enhanced.

FIG. 5 is a circuit diagram illustrating a liquid crystal display among various display devices with the thin film transistor of FIG. 1. FIG. 6A is a plan view of a liquid crystal display according to an exemplary embodiment. FIG. 6B is a cross-sectional view along section line I-I′ of FIG. 6A. The liquid crystal display device according to an embodiment includes a signal lines and pixels coupled to signal lines. The pixels corresponding to the plurality of signal lines may be arranged in a matrix.

Referring to FIG. 5, the signal lines include gate lines GL transmitting gate signals and data lines DL transmitting data signals. The gate lines GL may extend in a first direction (e.g., a row direction). The data lines DL may extend in a second direction crossing the first direction (e.g., a column direction).

The pixel may be coupled to a corresponding gate line GL among the gate lines GL and a corresponding data line DL among the data lines DL. The pixel may include a thin film transistor TFT, a liquid crystal capacitor Clc, and a storage capacitor Cst. A gate electrode 420 of the thin film transistor TFT may be coupled to the gate line GL, a source electrode 450a of the thin film transistor TFT may be coupled to the data line DL, and a drain electrode 450b of the thin film transistor TFT may be coupled to the liquid crystal capacitor Clc and a storage capacitor Cst coupled to a common voltage Vcom.

A turn on voltage may be applied to the gate electrode 420 of the thin film transistor TFT. The thin film transistor TFT may be turned on, and a data voltage may be charged to the liquid crystal capacitor Clc and the storage capacitor Cst coupled to the drain electrode 450b of the thin film transistor TFT. The storage capacitor Cst may maintain the charged data voltage after the thin film transistor TFT is turned off.

Referring to FIGS. 6A and 6B, a liquid crystal display device according to an exemplary embodiment includes a first substrate including a pixel electrode 470, a second substrate facing the first substrate and including a common electrode 510, and a liquid crystal layer LC provided between the first substrate and the second substrate.

The first substrate may be a thin film transistor substrate where thin film transistors TFT are formed to drive liquid crystal molecules of the liquid crystal layer LC. The first substrate may include a first base substrate 400, an insulating pattern 410 formed on the first base substrate 400 and an electronic device provided on the insulating pattern 410 and the first base substrate 400.

The first base substrate 400 may be a transparent substrate (e.g., glass, quartz, ceramic, and/or plastic). The first base substrate 400 may include a silicon substrate. The first base substrate 400 may include a flexible substrate (e.g., plastic).

The insulating pattern 410 may be provided on a surface of the first base substrate 400. The insulating pattern 410 may include a material with a high penetration ratio (e.g., at least one of silicon nitride (SiN_{X}), carbon-injected silicon oxide (SiOC), and an organic polymer).

The electronic device may include a gate line GL, a data line DL, a storage line STL, a thin film transistor, and the pixel electrode 470.

The gate line GL may extend in a first direction D1. The data line may extend in a second direction D2 crossing the first direction D1 and substantially perpendicular to the first direction D1. The storage line STL may be distanced apart from the gate line GL and extend in the first direction D1.

The gate line GL and the storage line STL, and the data line DL may be provided with a gate insulating layer 430 therebetween.

The thin film transistor may include a gate electrode 420, a semiconductor layer 440, a source electrode 450a, and a drain electrode 450b.

The gate electrode 420 may be provided on the insulating pattern 410. The gate electrode 420 may be an offshoot (i.e., a branch) of the gate line GL extending in the second direction D2 substantially perpendicular to the extending direction of the gate line GL. The gate electrode 420 may include a first portion 420a overlapping a portion of the surface of the first base substrate 400 along an edge of the insulating pattern 410, a second portion 420b contacting a side surface of the insulating pattern 410 and extending from the first portion 420a to a third portion 420c of the gate electrode 420. The third portion 420c may contact an upper surface of the insulating pattern 410 and extending from the second portion 420b to another part of the second portion 420b.

Since the second portion 420b of the gate electrode 420 surrounds the side surface of the insulating pattern 410 and extend vertically from the first portion 420a to the third portion 420c, a width of a line (i.e., a data line DL, a gate line GL, and/or a storage line STL) may be substantively reduced. The gate insulating layer 430 may be provided on the gate electrode 420.

The gate insulating layer 430 may be formed on the first base substrate 400 in accordance with the shape of the gate electrode 420. The gate insulating layer 430 may include an organic insulating material. The gate insulating layer 430 may include an inorganic insulating material (e.g., silicon oxide and/or silicon nitride).

The semiconductor layer 440 may include an active layer 440a and an ohmic contact layer 440b. The active layer 440a may be formed on the gate insulating layer 430, and no impurities may be injected into the active layer 440a. The ohmic contact layer 440b may be positioned on the active layer 440a, and impurities may be injected into the ohmic contact layer 440b. The impurities may vary depending on the type of the thin film transistor. The active layer 440a and the ohmic contact layer 440b may be formed on the gate insulating layer 430 in accordance with the shape of the gate electrode 420.

The source electrode 450a may offshoot (branch) from the data line DL at a substantially perpendicular direction (i.e., in the first direction D1) from the direction the data line DL extends. The source electrode 450a may be directly provided on the semiconductor layer 440 to cover a portion of the surface of the semiconductor layer 440. The source electrode 450a may include a first portion 450a-1 substantially parallel to the upper surface of the semiconductor layer 440 and a second portion 450a-2 substantially parallel to the side surface of the semiconductor layer 440.

The drain electrode 450b may be disposed on the semiconductor layer 440 to be distanced apart from the source electrode 450a. The drain electrode 450b may include a first portion 450b-1 substantially parallel to the upper surface of the semiconductor layer 440 and a second portion 450b-2 substantially parallel to the side surface of the semiconductor layer 440.

The source electrode 450a and/or the drain electrode 450b may be formed of a conductive material (e.g., a metal). The source electrode 450a and/or the drain electrode 450b may be formed of a single metal or two or more types of metal. The source electrode 450a and the drain electrode 450b may include an alloy of two or more metals. In addition, the source electrode 450a and/or the drain electrode 450b may be formed of a single layer or multiple layers.

The source electrode 450a and/or the drain electrode 450b may be formed on the upper surface and the side surface of the semiconductor layer 440. Accordingly, in the semiconductor layer 440, a channel portion may be formed both on the upper surface and the side surface of the semiconductor layer 440.

A protective layer 460 may be provided on the thin film transistor. The protective layer 460 may be formed on the source electrode 450a and the drain electrode 450b using an organic insulating layer and/or an inorganic insulating layer. The protective layer 460 may be formed of an inorganic insulating layer or a complex of an inorganic insulating layer and an organic insulating layer.

The protective layer 460 may include a contact hole CH exposing a portion of the drain electrode 450b. In other words, a portion of the drain electrode 450b is not covered by the protective layer. The pixel electrode 470 may be provided on the protective layer 460.

The pixel electrode 470 may be coupled to the drain electrode 450b through the contact hole CH. The pixel electrode 470 may be formed of a transparent conductive material. The pixel electrode 470 may be formed of a transparent conductive oxide (e.g., indium tin oxide (ITO), indium zinc oxide (IZO), and indium tin zinc oxide (ITZO)).

The pixel electrode 470 may overlap a portion of the storage line STL. The capacitor storage may be formed by the pixel electrode 470, the storage line STL, and the gate insulating layer 430 disposed between the pixel electrode 470 and the storage line STL.

The second substrate may include a second base substrate 500 facing the first base substrate 400 and a common electrode 510 provided on the second base substrate 500 and forming an electric field with the pixel electrode 470.

The second base substrate 500 may include a transparent substrate (e.g., as glass, quartz, ceramic, and/or plastic). The second base substrate 500 may include a silicon substrate. The second base substrate 500 may include a flexible substrate (e.g., plastic).

The liquid crystal layer LC may include liquid crystal molecules having dielectric anisotropy. The liquid crystal molecules of the liquid crystal layer LC may rotate in a certain direction between the first substrate and the second substrate when an electric field is applied between the first substrate and the second substrate. Accordingly, light which passes through the liquid crystal layer LC may be allowed to penetrate or may be blocked.

As for a liquid crystal display device having the structure described above, a conductive channel (hereinafter the “channel”) may be formed in the channel portion when a gate signal is provided to the gate electrode 420 by the gate line GL, and data signal is provided to the source electrode 450a by the data line DL. Accordingly, the thin film transistor is turned on and an image signal corresponding to the data signal is provided to the pixel electrode 470. An electric field may be formed between the pixel electrode 470 and the common electrode 510 where a common voltage is applied. In accordance with the electric field, the liquid crystal may be driven. As a result, according to an amount of light that passes through the liquid crystal layer LC, an image is displayed.

In an exemplary embodiment, a separate source of light which provides light may be provided since the liquid crystal display device is a light receiving element.

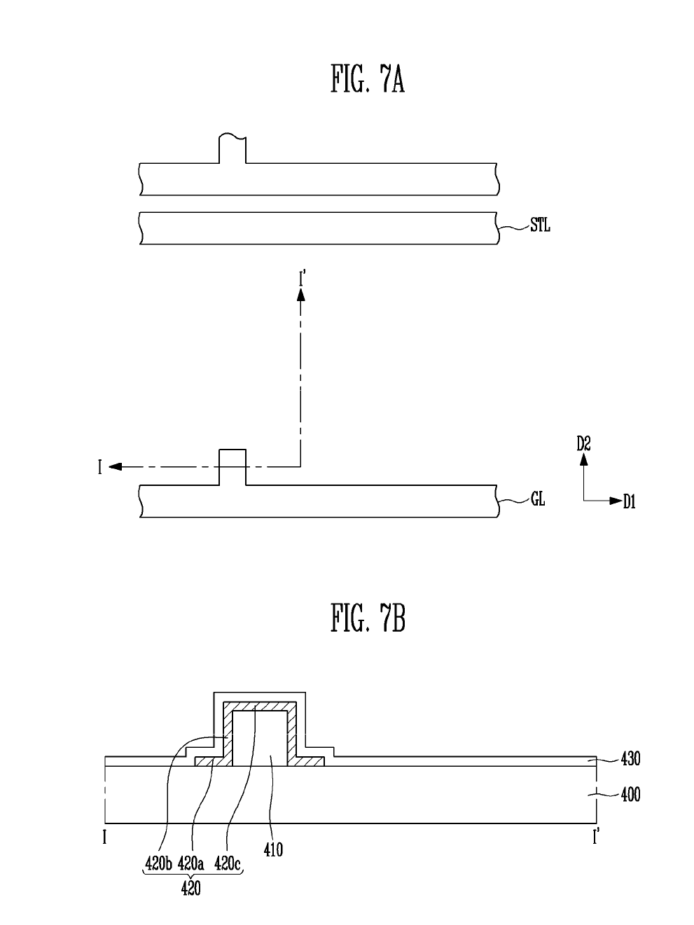

FIGS. 7A, 8A, 9A, and 10A are plan views of a method for manufacturing a liquid crystal display according to an exemplary embodiment. FIGS. 7B, 8B, 9B, and 10B illustrate cross-sectional views along section line I-I′ of FIGS. 7A, 8A, 9A, and 10A.

Referring to FIGS. 7A and 7B, an insulating pattern 410, a gate wire portion and a gate insulating layer 430 may be formed on a first base substrate 400.

The insulating pattern 410 may include a material with a high penetration ratio (e.g., at least one of silicon nitride (SiN_{X}), carbon-injected silicon oxide (SiOC), and an organic polymer). The insulating pattern 410 may be formed by patterning an insulating material layer formed on all surfaces of the first base substrate 400 with photolithography.

The gate wire portion may include a gate line GL, a gate electrode 420 and a storage line STL.

The gate wire portion may be formed of a conductive material (e.g., a metal). For example, but without limitation, the gate wire portion may be formed by patterning a metal layer formed on all surfaces of the first base substrate 400 with photolithography. The gate wire portion may be formed of a single layer made of a single metal or an alloy. However, the gate wire portion may include multiple layers made of a metal of two or more metals. The gate wire portion may include one or more alloys in multiple layers as well.

The gate electrode 420 may include a first portion 420a contacting a portion of the surface of the first base substrate 400, a second portion 420b contacting the side surface of the insulating pattern 410 and extending from the first portion 420a to a third portion 420c of the gate electrode. The third portion 420c may contact the upper surface of the insulating pattern 410 and extend from the second portion 420b.

Although not shown on the drawings, the gate line GL and the storage line STL may also be provided on the insulating pattern 410. If the gate line GL and the storage line STL are provided on the insulating pattern 410, the gate line GL and the storage line STL may extend along the side surface and the upper surface of the insulating pattern 410.

As each of the gate line GL and the storage line STL includes a vertical structure in which it extends along the side surface of the insulating pattern 410, the widths of the line of the gate line GL and the storage line STL may be reduced. As the widths of the line of the gate line GL and that of the storage line STL are reduced, the opening ratio in the display device according to an exemplary embodiment may be improved. Also, wire resistance may be reduced, thereby reducing signal delay (RC delay) phenomenon.

The gate insulating layer 430 may include an organic insulating material and/or an inorganic insulating material. For example but without limitation, the gate insulating layer 430 may be formed of silicon oxide or silicon nitride.

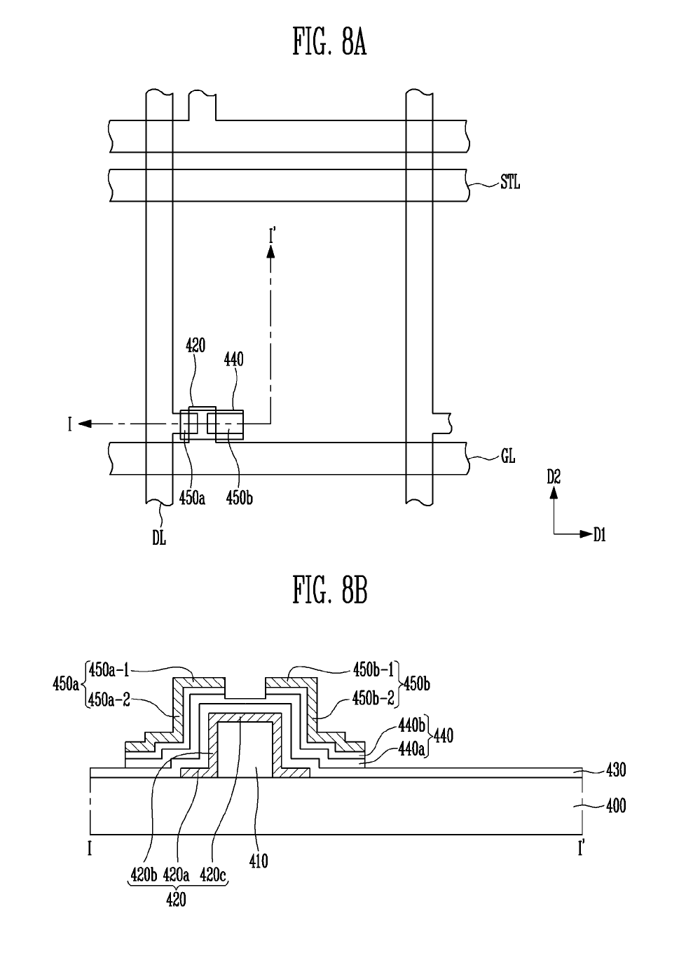

Referring to FIGS. 8A and 8B, a semiconductor layer 440 and a data wire portion may be provided on the gate insulating layer 430. The data wire portion may include a data line DL, a source electrode 450a, and a drain electrode 450b.

The semiconductor layer 440 and the data wire portion may be formed by patterning using a photolithography process which sequentially forms a silicon layer, an impurity amorphous silicon layer, and a metal layer on all surfaces of the gate insulating layer 430 and which uses a half-tone mask.

Here, the amorphous silicon layer may form an active layer 440a of the semiconductor layer 440, and the impurity amorphous silicon layer may form an ohmic contact layer 440b of the semiconductor layer 440. The active layer 440a and the ohmic contact layer 440b may be formed on the gate insulating layer 430 according to the shape of the gate electrode 420.

The semiconductor layer 440 may be provided on an upper part of the gate electrode 420. The semiconductor layer 440 may overlap at least a portion of the gate electrode 420, from a planar view. In addition, the semiconductor layer 440 may be provided on lower parts of the source electrode 450a and the drain electrode 450b. The semiconductor layer 440 may be formed, identical to the side surface of the source electrode 450a and the side of the drain electrode 450b, from a planar view.

In the semiconductor layer 440, an area between the source electrode 450a and the drain electrode 450b may be a channel portion.

The source electrode 450a may offshoot (branch) from the data line DL. In other words, the source electrode 450a may be form with the data line DL, but may extend substantially perpendicular direction (D1) compared to the extending direction of the data line DL (D2). The source electrode 450a may include a first portion 450a-1 substantially parallel to the upper surface of the semiconductor layer 440 and a second portion 450a-2 substantially parallel to the side surface of the semiconductor layer 440.

The drain electrode 450b may be provided on the semiconductor layer 440 such that it is distanced away from the source electrode 450a. The drain electrode 450b may include a first portion 450b-1 substantially parallel to the upper surface of the semiconductor layer 440 and a second portion 450b-2 substantially parallel to the side surface of the semiconductor layer 440.

The data line DL, the source electrode 450a, and/or the drain electrode 450b may include a conductive material (e.g., a metal). The data line DL, the source electrode 450a, and/or the drain electrode 450b may include a single metal or metals of two or more types of metal. The data line DL, the source electrode 450a, and/or the drain electrode 450b may include an alloy of two or more types of metals. Also, the data line DL, the source electrode 450a, and/or the drain electrode 450b may include a single layer and/or multiple layers.

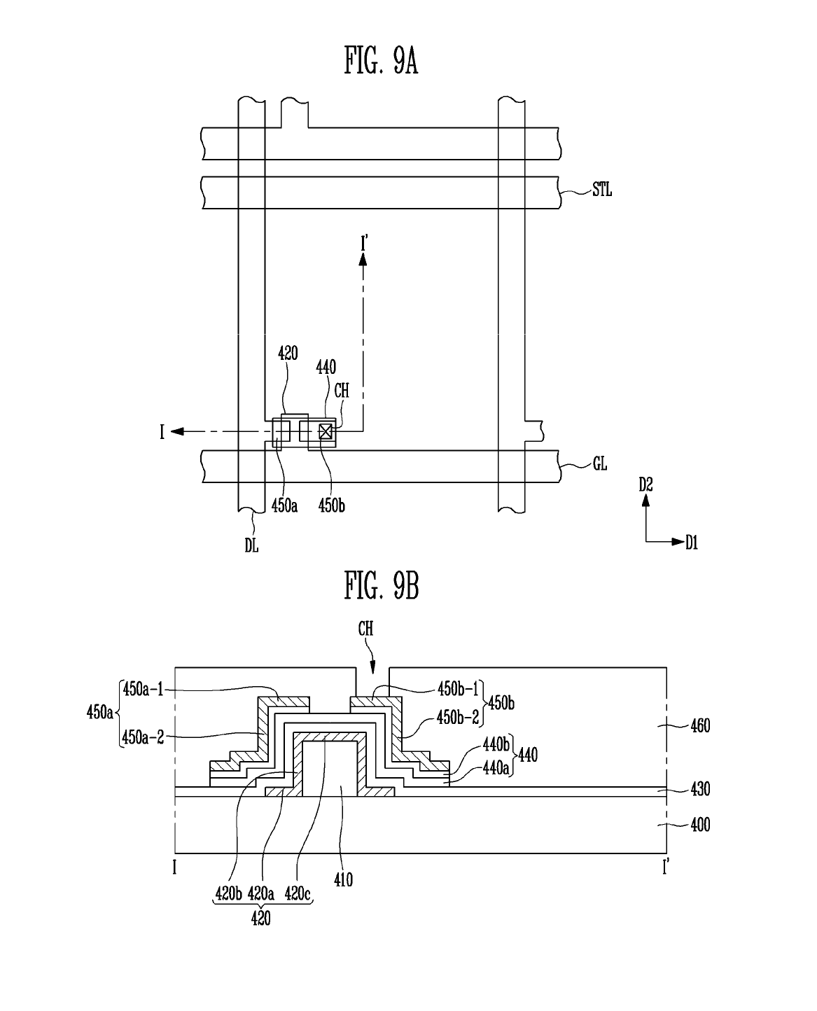

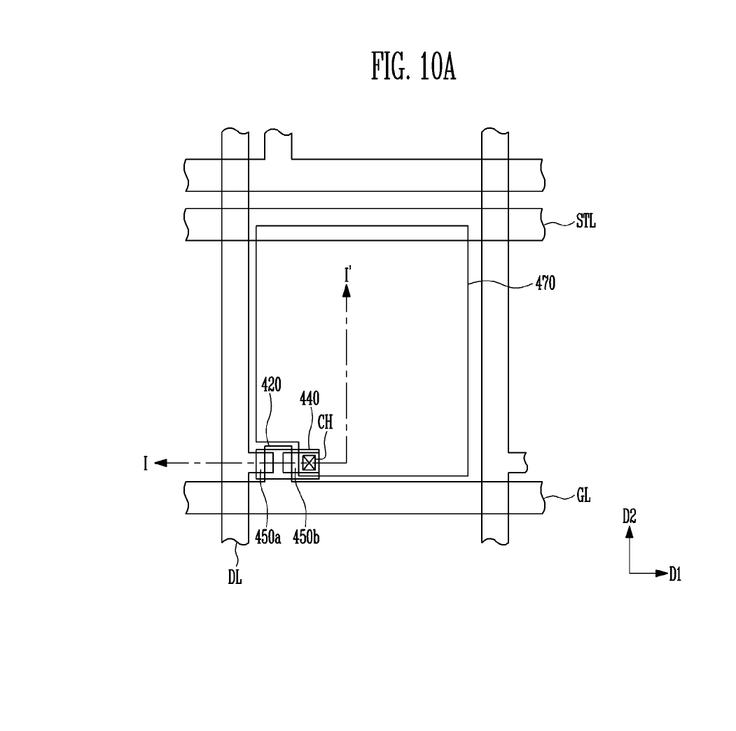

Referring to FIGS. 9A and 9B, a protective layer 460 may be formed of an insulating material on the first base substrate 400 where the semiconductor layer 440, the source electrode 450a, and the drain electrode 450b are formed. A contact hole CH that exposes a portion of the drain electrode 450b using photolithography may be formed at the protective layer 460.

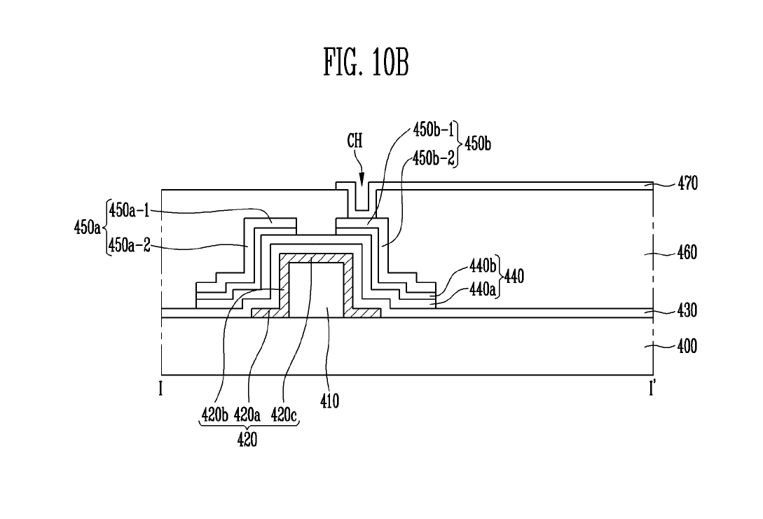

Referring to FIGS. 10A and 10B, a pixel electrode 470 may be formed on the first base substrate 400 where the protective layer 460 is formed. The pixel electrode 470 may be formed by patterning a conductive layer using photolithography after forming the conductive layer with a conductive material. The pixel electrode 470 may be coupled to the drain electrode 450b through the contact hole CH. The pixel electrode 470 may be formed of a transparent material.

Although not shown, the first substrate may be disposed to face a second substrate. A liquid crystal layer LC may be formed between the first substrate and the second substrate. The second substrate may be formed by forming a common electrode 510 on a second base substrate 500. The common electrode 510 may be formed of a transparent conductive material.

A person skilled in the art will understand that the invention described herein may be practiced in any other concrete form without changing the technological concept or the essential features.

For example, but without limitation, the thin film transistor in an exemplary embodiment is described as being used in a display device. However, this should not be so limited. It may be certainly used in other electronic device where thin film transistor is used. Also, as an example of another display device according to an exemplary embodiment, a liquid crystal display device was given. However, it is not limited to liquid crystal display devices, and different display devices (e.g., organic light emitting display device, an electrophoretic display device, and an electro-wetting display device) may certainly be used.

By way of summation and review, a thin film transistor having a fast driving speed may be formed according to an exemplary embodiment. Also, it may be possible to drive a thin film transistor in a reliable manner by minimizing a parasitic capacitance capable of occurring between a gate electrode and a source electrode of a thin film transistor, or between the gate electrode and a drain electrode. The display devices according to the described exemplary embodiments may improve opening ratio by forming a vertical-structured wires and electrodes.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A thin film transistor, comprising:
an insulating pattern disposed on a substrate;
a gate electrode disposed on the insulating pattern;
a gate insulating layer disposed on the gate electrode;
a semiconductor layer disposed on the gate insulating layer; and
a source electrode and a drain electrode, the source electrode and the drain electrode being disposed on the semiconductor layer and distanced apart from each other,
wherein the gate electrode surrounds an upper surface and a side surface of the insulating pattern and overlaps a first portion of a substrate surface.

2. The thin film transistor of claim 1, wherein the gate electrode comprises:
a first portion contacting the first portion of the substrate surface along a first direction; and
a second portion contacting the side surface of the insulating pattern and extending from the first portion of the gate electrode to a third portion of the gate electrode along a second direction that substantially perpendicular to the first direction, the third portion of the gate electrode contacting the upper surface of the insulating pattern and extending from the second portion of the gate electrode to another part of the second portion of the gate electrode.

3. The thin film transistor of claim 1, wherein the insulating pattern comprises at least one of silicon nitride (SiN_{X}), carbon-injected silicon oxide (SiOC), and an organic polymer.

4. The thin film transistor of claim 1, further comprising a filling layer covering a side surface of the gate electrode between the gate electrode and the gate insulating layer.

5. The thin film transistor of claim 4, wherein the filling layer comprises at least one of a transparent insulating material and a color filter layer.

6. The thin film transistor of claim 1, wherein the insulating pattern comprises an opening portion exposing a second portion of the substrate surface.

7. The thin film transistor of claim 6, wherein the gate electrode is disposed in the opening portion.

8. A method of manufacturing a thin film transistor, comprising:
forming an insulating pattern on a substrate;
forming a gate electrode on the insulating pattern;
forming a gate insulating layer on the gate electrode;
forming a semiconductor layer on the gate insulating layer; and
forming a source electrode and a drain electrode on the semiconductor layer, the source electrode and the drain electrode being distanced apart from each other on the semiconductor layer,
wherein the gate electrode surrounds an upper surface and a side surface of the insulating pattern and overlaps a first portion of a substrate surface.

9. The method of claim 8, wherein the forming of the gate electrode comprises:
forming a conductive layer on the insulating pattern and the substrate;
forming a photoresist pattern on the conductive layer;
forming the gate electrode by etching the conductive layer; and
removing the photoresist pattern.

10. The method of claim 9, wherein the etching of the conductive layer comprises an anisotropic etching method.

11. The method of claim 8, wherein the insulating pattern comprises at least one of silicon nitride (SiN_{X}), carbon-injected silicon oxide (SiOC), and an organic polymer.

12. The method of claim 8, further comprising forming a filling layer between the gate electrode and the gate insulating layer and covering a side surface of the gate electrode.

13. The method of claim 12, wherein the filling layer comprises at least one of a transparent insulating material and a color filter.

14. The method of claim 8, wherein the insulating pattern comprises an opening portion exposing a second portion of the substrate surface.

15. A display device, comprising:
a display element; and
a thin film transistor configured to provide a driving signal to the display element,
wherein the thin film transistor comprises:
an insulating pattern disposed on a substrate;
a gate electrode disposed on the insulating pattern;
a gate insulating layer disposed on the gate electrode;
a semiconductor layer disposed on the gate insulating layer; and
a source electrode and a drain electrode disposed on the semiconductor layer, the source electrode and the drain electrode being disposed to be distanced apart from each other,
wherein the gate electrode surrounds an upper surface and a side surface of the insulating pattern and overlaps a portion of a substrate surface.

16. The display device of claim 15, wherein the display device comprises:
a first electrode coupled to the thin film transistor;
a second electrode configured to form an electric field along with the first electrode; and
a liquid crystal layer configured to be driven by the electric field.

17. The display device of claim 15, wherein the display device comprises:
a first electrode coupled to the thin film transistor;
an organic light emitting layer disposed on the first electrode; and
a second electrode disposed on the organic light emitting layer and configured to drive the organic light emitting layer along with the first electrode.
